(19) United States
(12) Patent Application Publication
(10) Pub. No.: US 2024/0154388 A1
(43) Pub. Date: May 9, 2024

(54) EXTERNAL CAVITY LASER AND TUNING METHOD THEREFOR

(71) Applicant: InnoLight Technology (Suzhou) Ltd., Suzhou (CN)

(72) Inventors: Chen-lei LI, Suzhou (CN); Xue-zhe ZHENG, Suzhou (CN)

(21) Appl. No.: 18/412,828

(22) Filed: Jan. 15, 2024

Related U.S. Application Data
(63) Continuation of application No. PCT/CN2022/093064, filed on May 16, 2022.

(30) Foreign Application Priority Data
Jul. 15, 2021 (CN) 202110809494.8

(51) Int. Cl. H01S 5/14; H01S 5/026; H01S 5/042; H01S 5/06; H01S 5/10

(52) U.S. Cl. CPC H01S 5/141; H01S 5/026; H01S 5/04256; H01S 5/0612; H01S 5/1007

(57) ABSTRACT

An external cavity laser and a tuning method therefor are provided. The external cavity laser includes a gain chip, and a tunable reflector. The tunable reflector includes a main waveguide, a beam splitter, a first branch waveguide, a first photonic crystal modulator, a second branch waveguide, and a second photonic crystal modulator. The beam splitter is configured to equally split the optical signal transmitted by the main waveguide into a first optical signal and a second optical signal and is configured to transmit the first optical signal to a first branch waveguide and the second optical signal to a second branch waveguide. A first photonic crystal modulator is configured to tune the first optical signal transmitted by the first branch waveguide. A second photonic crystal modulator is configured to tune the second optical signal transmitted by the second branch waveguide.

### CROSS-REFERENCE TO RELATED PATENT APPLICATION

This application is a continuation application of International Patent Application Ser. No. PCT/CN2022/093064, filed on May 16, 2022, which the international application was published on Jan. 19, 2023, as International Publication No. WO 2023/284400A1, and claims the priority of China Patent Application No. CN202110809494.8, filed on Jul. 15, 2021 in People's Republic of China. The entirety of each of the above patent applications is hereby incorporated by reference herein and made a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to optical communications technologies, and more particularly to an external cavity laser and a tuning method using the same.

### BACKGROUND OF THE DISCLOSURE

At present, external cavity lasers are developing in the direction of small size, low power consumption and high speed. This also makes external cavity lasers receive more and more attention in the application of optical communication technology.

In related technologies, external cavity lasers mostly use microring resonators (also called microring modulators) as their external cavity reflectors, so that the hybrid integration of the microring resonator and the semiconductor gain chip can be used to achieve high-speed direct modulation of the laser.

However, limited by the free spectral range of the microring, the microring resonator is a narrowband device, and its resonance peak needs to be precisely adjusted and controlled to match the wavelength of the input light from the light source. Moreover, once the resonance peak of the microring resonator drifts, its reflectivity to the semiconductor gain chip will also change accordingly, making the light field in the microring resonator unstable, and thus affecting the quality of the optical signal tuned by the microring resonator.

### SUMMARY OF THE DISCLOSURE

### Technical Problem

Based on this, embodiments of the present disclosure provide an external cavity laser and a tuning method using the same, which can ensure efficient and stable light output of the laser based on laser miniaturization and high-speed direct modulation.

### Solution of the Problem

### Technical Solution

In order to achieve the above purpose, in one aspect, some embodiments of the present disclosure provide an external cavity laser. The external cavity laser includes a gain chip, and a tunable reflector coupled with the gain chip. The tunable reflector includes a main waveguide, a beam splitter, a first branch waveguide, a first photonic crystal modulator, a second branch waveguide, and a second photonic crystal modulator. In addition, the main waveguide is coupled to the gain chip and is configured to receive an optical signal transmitted by the gain chip. The beam splitter is coupled to the main waveguide and is configured to equally split the optical signal transmitted by the main waveguide into a first optical signal and a second optical signal. The first branch waveguide is coupled to the beam splitter and is configured to receive the first optical signal. The first photonic crystal modulator is arranged beside the first branch waveguide and is configured to tune the first optical signal transmitted by the first branch waveguide. The second branch waveguide is coupled to the beam splitter and is configured to receive the second optical signal. The second photonic crystal modulator is arranged beside the second branch waveguide and is configured to tune the second optical signal transmitted by the second branch waveguide.

In the embodiment of the present disclosure, the gain chip and the tunable reflector can jointly form an FP cavity of the external cavity laser. After the gain chip transmits the optical signal to the main waveguide of the tunable reflector, the beam splitter can be used to split the optical signal transmitted by the main waveguide into the first optical signal and the second optical signal, and then the first photonic crystal modulator is used to tune the first optical signal, and the second photonic crystal modulator is used to tune the second optical signal. In this way, under the tuning effect of the first photonic crystal modulator and the second photonic crystal modulator, as well as the action of beam reflection and beam interference in the FP cavity, the optical signal can be output directly and quickly from an output port of the external cavity laser, and thereby achieving high-speed direct modulation of external cavity laser.

In some embodiments, the tunable reflector further includes a common waveguide.

The first photonic crystal modulator is arranged on one side of the first branch waveguide close to the second branch waveguide, and the second photonic crystal modulator is arranged on one side of the second branch waveguide close to the first branch waveguide. The common waveguide is arranged between the first photonic crystal modulator and the second photonic crystal modulator.

The common waveguide is configured to receive the first optical signal tuned by the first photonic crystal modulator, and transmit the tuned first optical signal to a resonant cavity of the second photonic crystal modulator, so as to be coupled to the second branch waveguide after the secondary tuning by the second photonic crystal modulator; and, to receive the second optical signal tuned by the second photonic crystal modulator, and transmit the tuned second optical signal to a resonant cavity of the first photonic crystal modulator, so as to be coupled to the first branch waveguide after the secondary tuning by the first photonic crystal modulator.

In the embodiment of the present disclosure, the common waveguide is located between the first photonic crystal modulator and the second photonic crystal modulator. In this way, secondary tunings of the first optical signal and the second optical signal can be achieved through the common waveguide, that is, push-pull tunings of the first optical signal and the second optical signal in the FP cavity can be achieved, so as to realize the tuning of the optical signal to a vast extent, and allow the tuning of the first optical signal and the second optical signal to have the same optical path (shift).

For instance, after the optical signal is equally split into the first optical signal and the second optical signal, the first photonic crystal modulator and the second photonic crystal modulator can perform anti-phase modulation of the two optical signals. That is, under the action of the same input electrical signal, resonance peaks of the first photonic crystal modulator and the second photonic crystal modulator are moved in opposite directions. Therefore, when the first optical signal and the second optical signal are secondary tuned by the first photonic crystal modulator and the second photonic crystal modulator, respectively, the change in the resonance peaks between the first photonic crystal modulator and the second photonic crystal modulator can offset the change in the beam reflection in the FP cavity during the modulation process of the first optical signal and the second optical signal to ensure that the FP cavity has stable light reflectivity and stable light field. The operating state of the gain chip is no longer affected by the modulation signal, thereby ensuring efficient and stable light emission of the external cavity laser.

In some embodiments, the tunable reflector further includes a lower cladding layer and an upper cladding layer arranged opposite to each other. The main waveguide, the beam splitter, the first branch waveguide, the first photonic crystal modulator, the second branch waveguide, the second photonic crystal modulator, and the common waveguide are respectively arranged between the lower cladding layer and the upper cladding layer.

In some embodiments, an upper surface of the lower cladding layer is provided with a semiconductor layer. The tunable reflector further includes a first electrode, a second electrode, and a common electrode disposed on an upper surface of the upper cladding layer. The first electrode, the second electrode, and the common electrode are respectively connected to the semiconductor layer via through holes in the upper cladding layer.

The first photonic crystal modulator is arranged between the first electrode and the common electrode and is configured to tune the optical signal under the action of the electrical signal provided by the first electrode and the common electrode. The second photonic crystal modulator is arranged between the second electrode and the common electrode and is configured to tune the optical signal under the action of the electrical signal provided by the second electrode and the common electrode.

In this way, the first electrode and the common electrode respectively provide different voltage signals, and the bias voltage between them can be used to adjust the resonance peak of the first photonic crystal modulator. The second electrode and the common electrode respectively provide different voltage signals, and the bias voltage between them can be used to adjust the resonance peak of the second photonic crystal modulator.

In some embodiments, an orthogonal projection of the common waveguide on the upper cladding layer is a “U” shape. In this way, on the basis of ensuring that the common waveguide can meet the requirements of optical signal transmission, the spatial position of each component in the tunable reflector can be set more reasonably, which is beneficial to reducing the plane area of the tunable reflector, so as to reduce the integral size of the external cavity laser, thereby increasing the optical modulation speed of the external cavity laser.

Optionally, the common electrode is located in a concave area of the orthographic projection of the common waveguide on the upper cladding layer.

In some embodiments, the tunable reflector further includes a first heating layer and a second heating layer. In addition, the first heating layer is disposed on the upper surface of the upper cladding layer and is located within an orthographic projection range of the first photonic crystal modulator on the upper cladding layer. The second heating layer is disposed on the upper surface of the upper cladding layer and is located within an orthographic projection range of the second photonic crystal modulator on the upper cladding layer. In this way, after heating by the first heating layer, the effective refractive index of the first photonic crystal modulator can be changed, thereby adjusting the resonance peak of the first photonic crystal modulator. In the same way, after heating by the second heating layer, an effective refractive index of the second photonic crystal modulator can be changed, thereby adjusting the resonance peak of the second photonic crystal modulator.

Based on this, through the first heating layer and the second heating layer, the resonance peak of the first photonic crystal modulator and the resonance peak of the second photonic crystal modulator can be independently adjusted to ensure that the resonance peaks of the first photonic crystal modulator and the second photonic crystal modulator are consistent with each other, thereby compensating for the resonance peak deviation issue caused by factors such as processing errors, improving the modulation efficiency of the tunable reflector, and ensuring its light reflectivity, so as to further ensure efficient and stable light emission from the external cavity laser.

In other embodiments, the first branch waveguide extends along a first direction, and the second branch waveguide extends along a second direction; the first direction and the second direction respectively intersect with a transmission direction of the main waveguide, and are symmetrical with the transmission direction of the main waveguide as the center. The first photonic crystal modulator is arranged beside the first branch waveguide along the first direction, and the second photonic crystal modulator is arranged beside the second branch waveguide along the second direction.

Tunable reflector further includes common waveguide. The common waveguide is disposed on a side of the first photonic crystal modulator away from the first branch waveguide, and on a side of the second photonic crystal modulator away from the second branch waveguide. The common waveguide is configured to receive the first optical signal tuned by the first photonic crystal modulator and transmit the tuned first optical signal into the resonant cavity of the second photonic crystal modulator, so as to be coupled to the second branch waveguide after being secondary tuning by the second photonic crystal modulator; and, to receive the second optical signal tuned by the second photonic crystal modulator, and transmit the tuned second optical signal to the resonant cavity of the first photonic crystal modulator, so as to be coupled to the first branch waveguide after being secondary tuning by the first photonic crystal modulator.

Optionally, the common waveguide includes a straight waveguide.

The technical effects achieved by the common waveguide in the embodiments of the present disclosure are the same as those of the common waveguides in some of the foregoing embodiments, and will not be reiterated herein.

In some embodiments, the tunable reflector further includes a first phase shifter and a second phase shifter. In addition, the first phase shifter is coupled to the first branch waveguide and is configured to adjust a phase of the first optical signal received by the first branch waveguide. The second phase shifter is coupled to the second branch waveguide and is configured to adjust a phase of the second optical signal received by the second branch waveguide. In this way, the phases of the first optical signal and the second optical signal are independently adjusted to keep the phases consistent with each other, so as to avoid differences between the first optical signal and the second optical signal due to factors such as process errors or design errors, which may lead to unstable light fields in the FP cavity. This helps ensure that the laser's light output is efficient and stable.

In some embodiments, the tunable reflector further includes a wavelength modulator. In addition, the wavelength adjuster is coupled to the main waveguide and is configured to adjust the wavelength of the optical signal received by the main waveguide. In this way, by using the wavelength adjuster to adjust the wavelength of the optical signal received by the main waveguide, the wavelength of the optical signal transmitted by the gain chip to the main waveguide can be matched with operating wavelengths of the first photonic crystal modulator and the second photonic crystal modulator, so as to ensure that the operating output (i.e. output power) of the gain chip would not affected by changes in the modulation states of the first photonic crystal modulator and the second photonic crystal modulator.

In some embodiments, the first photonic crystal modulator and the second photonic crystal modulator each include one photonic crystal modulation structure, or a plurality of cascaded photonic crystal modulation structures. In this way, the optical signal located at the resonance peak after being tuned by each photonic crystal modulation structure can enter the adjacent or opposite photonic crystal modulation structure to realize the tuning of the optical signal to a vast extent, and it is beneficial to improve the tuning efficiency and tuning quality of the optical signal by the first photonic crystal modulator and the second photonic crystal modulator.

Optionally, the photonic crystal modulation structure includes a one-dimensional photonic crystal nanobeam cavity structure or a two-dimensional photonic crystal flat plate structure.

Optionally, the photonic crystal modulation structure includes a cylindrical array structure, a fishbone structure, or a hole array structure.

In some embodiments, the beam splitter includes: a Y-branch waveguide, a 1><2 multimode interference coupler, a 2><2 multimode interference coupler, or a directional coupler with a beam splitting ratio of 50:50.

In another aspect, some embodiments of the present disclosure provide a tuning method for an external cavity laser. The tuning method includes the following steps.

A main waveguide receives an optical signal transmitted by a gain chip and transmits the optical signal to a beam splitter.

The beam splitter splits the optical signal into a first optical signal and a second optical signal, transmits the first optical signal to a first branch waveguide, and transmits the second optical signal to a second branch waveguide.

A first photonic crystal modulator tunes the first optical signal transmitted by the first branch waveguide.

A second photonic crystal modulator tunes the second optical signal transmitted by the second branch waveguide.

In some embodiments, the tuning method of the external cavity laser further includes the following steps.

The first photonic crystal modulator couples the tuned first optical signal to a common waveguide, and the common waveguide transmits the tuned first optical signal into a resonant cavity of the second photonic crystal modulator, and the second photonic crystal modulator performs secondary tuning on the tuned first optical signal, and couples the secondarily tuned first optical signal to the second branch waveguide.

The second photonic crystal modulator couples the tuned second optical signal to the common waveguide, and the common waveguide transmits the tuned second optical signal into a resonant cavity of the first photonic crystal modulator, and the first photonic crystal modulator performs secondary tuning on the tuned second optical signal, and couples the secondarily tuned second optical signal to the first branch waveguide.

In some embodiments, the tuning method of the external cavity laser further includes the following steps.

A resonant peak of the first photonic crystal modulator is adjusted through a first heating layer so that the resonant peak of the first photonic crystal modulator is consistent with a resonant peak of the second photonic crystal modulator.

The resonant peak of the second photonic crystal modulator is adjusted through the second heating layer so that the resonant peak of the second photonic crystal modulator is consistent with the resonant peak of the first photonic crystal modulator.

In some embodiments, the tuning method of the external cavity laser further includes the following steps.

Before the main waveguide transmits the optical signal to the beam splitter, the wavelength of the optical signal is adjusted by the wavelength adjuster so that the wavelength of the optical signal is consistent with an operating wavelength of the first photonic crystal modulator and an operating wavelength of the second photonic crystal modulator.

In some embodiments, the tuning method of the external cavity laser further includes the following steps.

Before the first photonic crystal modulator tunes the first optical signal transmitted through the first branch waveguide, a phase of the first optical signal is adjusted through a first phase shifter so that the phase of the first optical signal is consistent with a phase of the second optical signal.

Before the second photonic crystal modulator tunes the second optical signal transmitted through the second branch waveguide, the phase of the second optical signal is adjusted through a second phase shifter so that the phase of the second optical signal is consistent with the phase of the first optical signal.

### Beneficial Effect of the Disclosure

### Beneficial Effect

The tuning method of the external cavity laser provided by the embodiments of the present disclosure is applied to the external cavity laser in some of the foregoing embodiments. The aforementioned technical effects that can be achieved by external cavity lasers can also be achieved by this tuning method, and will not be reiterated herein.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

### Description of the Drawings

In order to more clearly illustrate the technical solutions of the embodiments of this disclosure or the related art, the drawings needed to be used in the description of the embodiments or the related art will be briefly introduced herein below. It is apparent that the drawings in the following description are only some embodiments of this disclosure, and for an ordinary person skilled in the art, other drawings may also be obtained according to these drawings without making creative efforts.

The described embodiments may be better understood by reference to the following description and the accompanying drawings, in which:

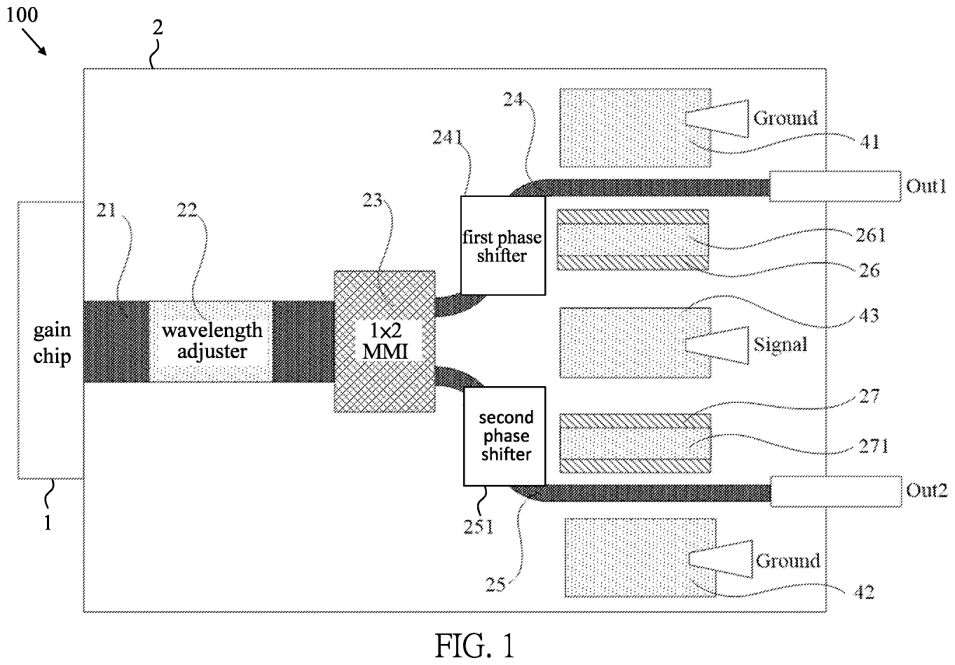

FIG. 1 is a schematic stereoscopic view of a structure of a tunable reflector in an external cavity laser according to one embodiment;

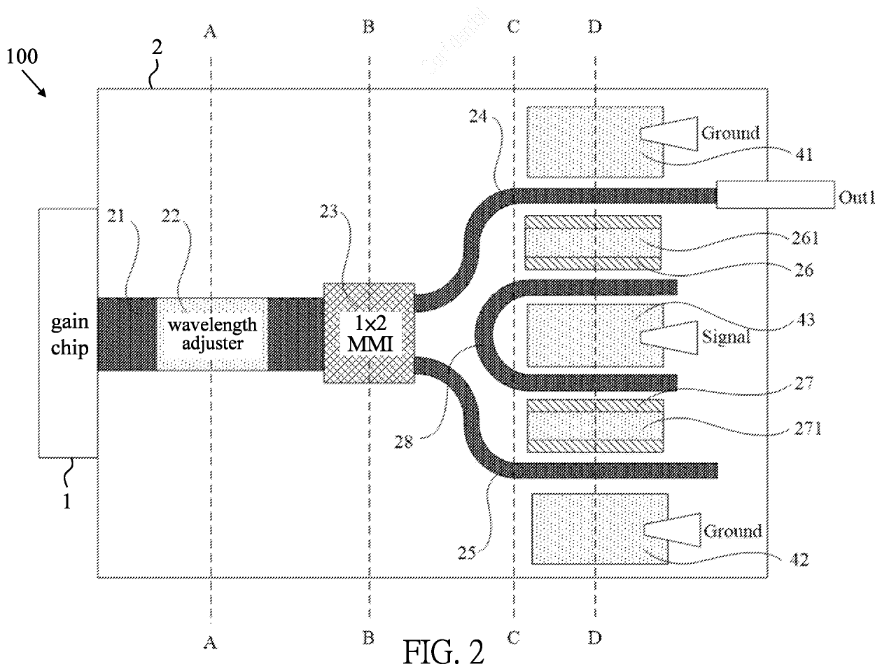

FIG. 2 is a schematic stereoscopic view of a structure of a tunable reflector in another external cavity laser according to one embodiment;

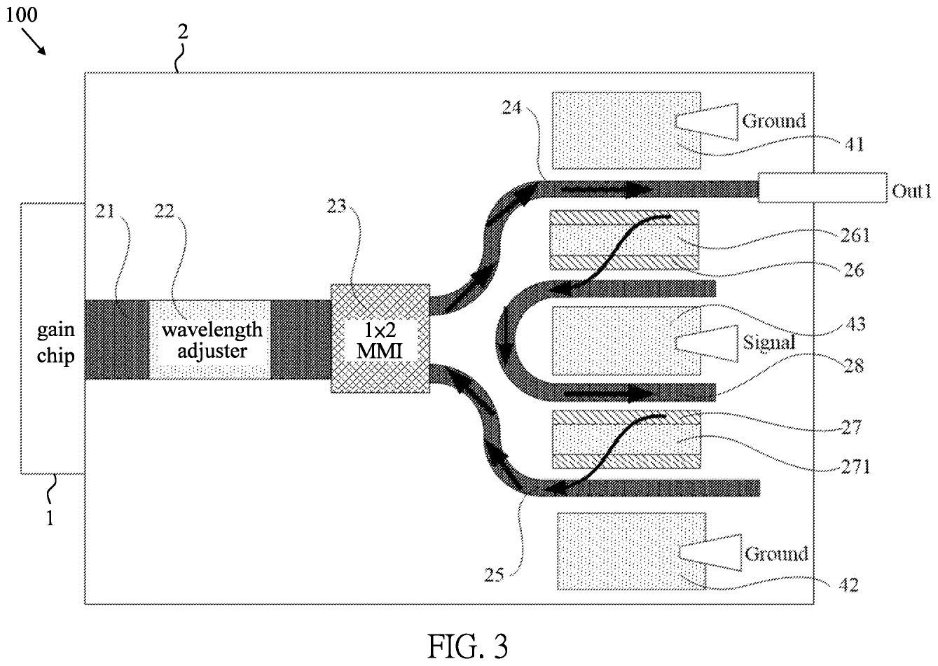

FIG. 3 is a tuning path view of a first optical signal in the tunable reflector shown in FIG. 2;

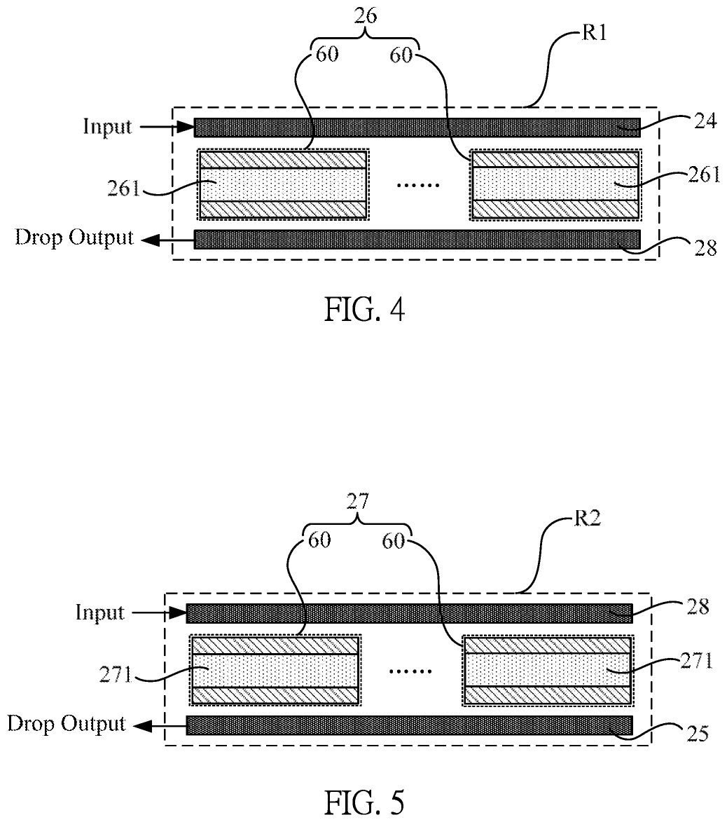

FIG. 4 is a schematic view of a resonant cavity of a second photonic crystal modulator in the tuning path of the first optical signal shown in FIG. 3;

FIG. 5 is a schematic view of a resonant cavity of a first photonic crystal modulator in the tuning path of the first optical signal shown in FIG. 3;

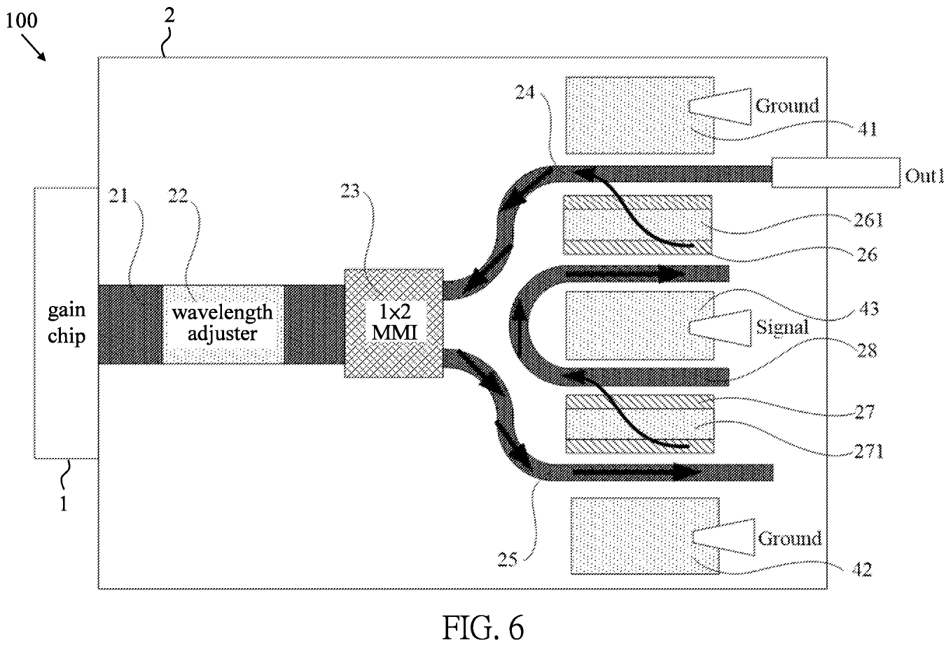

FIG. 6 is a tuning path view of a second optical signal in the tunable reflector shown in FIG. 2;

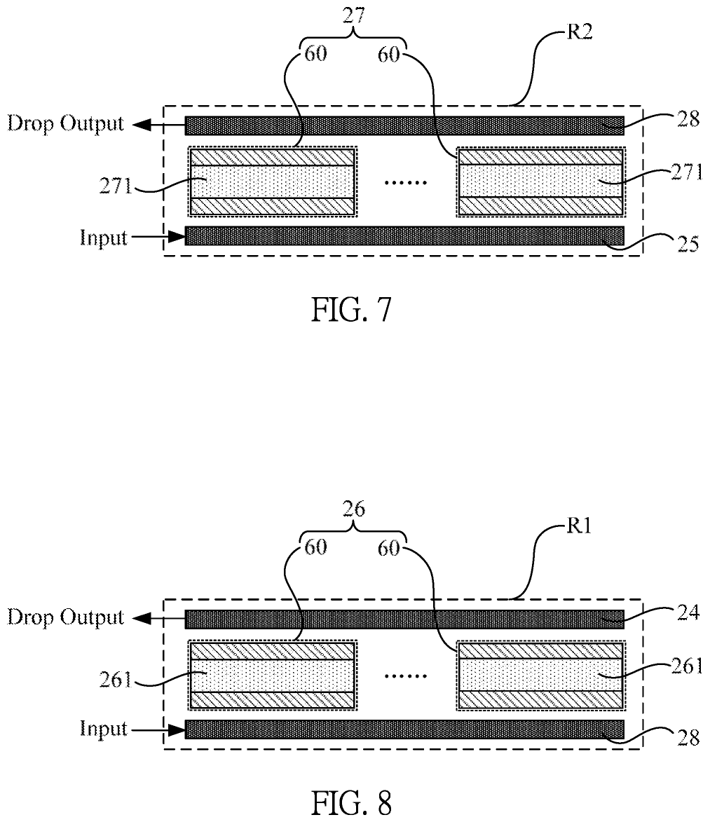

FIG. 7 is a schematic view of the resonant cavity of the second photonic crystal modulator in the tuning path of the second optical signal shown in FIG. 6;

FIG. 8 is a schematic view of the resonant cavity of the first photonic crystal modulator in the tuning path of the second optical signal shown in FIG. 6;

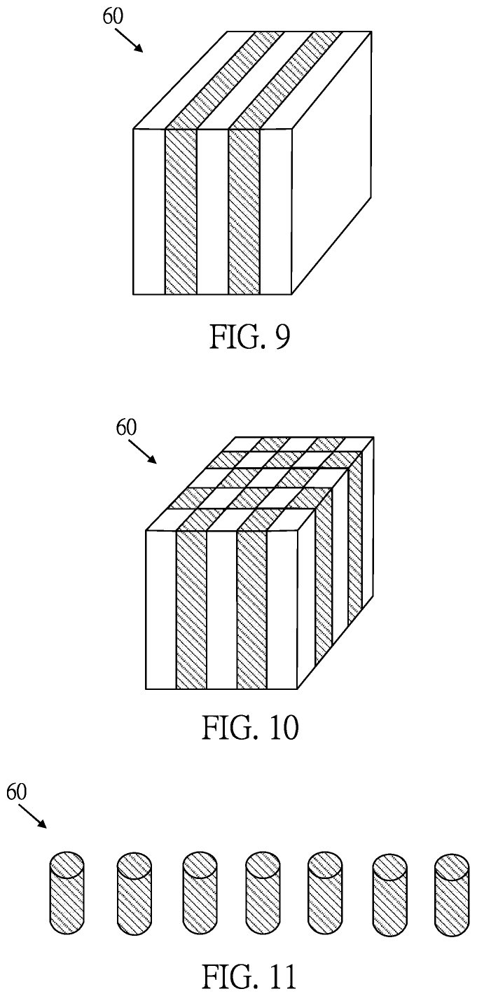

FIG. 9 is a schematic stereoscopic view of a one-dimensional photonic crystal cavity structure according to one embodiment;

FIG. 10 is a schematic stereoscopic view of a two-dimensional photonic crystal cavity structure according to one embodiment;

FIG. 11 is a schematic stereoscopic view of a photonic crystal modulator structure using a cylindrical array structure according to one embodiment;

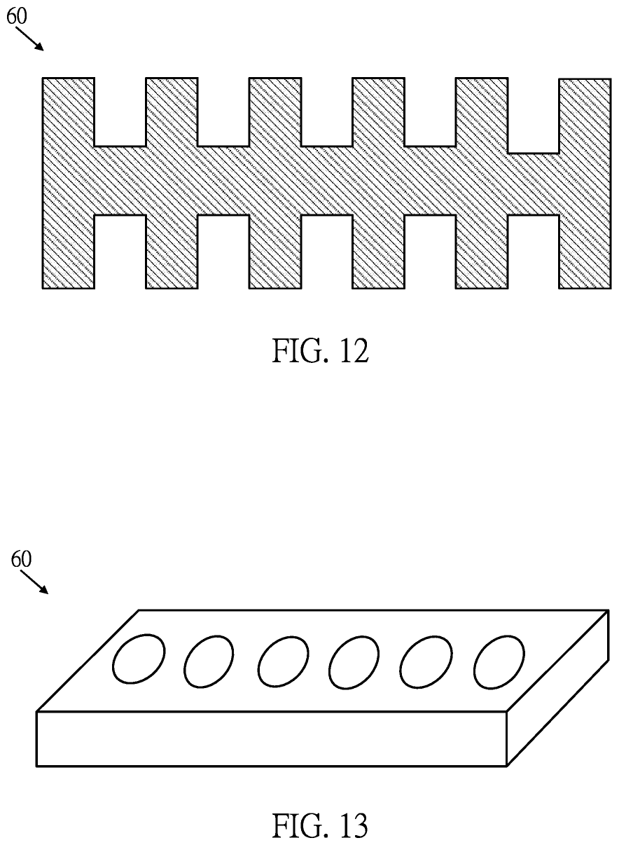

FIG. 12 is a schematic stereoscopic view of a photonic crystal modulator structure using a fishbone structure according to one embodiment;

FIG. 13 is a schematic stereoscopic view of a photonic crystal modulator structure using a hole array structure according to one embodiment;

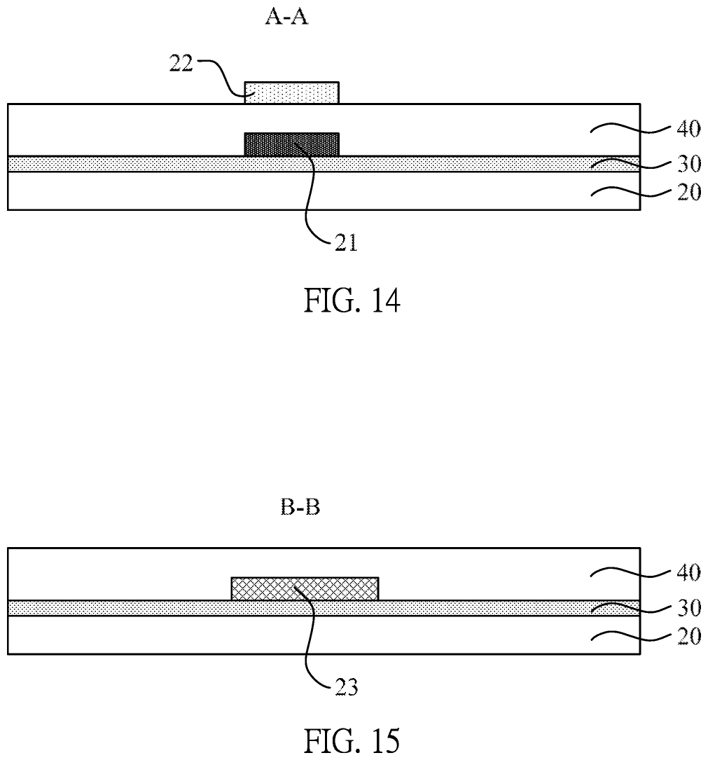

FIG. 14 is a schematic cross-sectional view taken along line A-A of the tunable reflector shown in FIG. 2;

FIG. 15 is a schematic cross-sectional view taken along line B-B of the tunable reflector shown in FIG. 2;

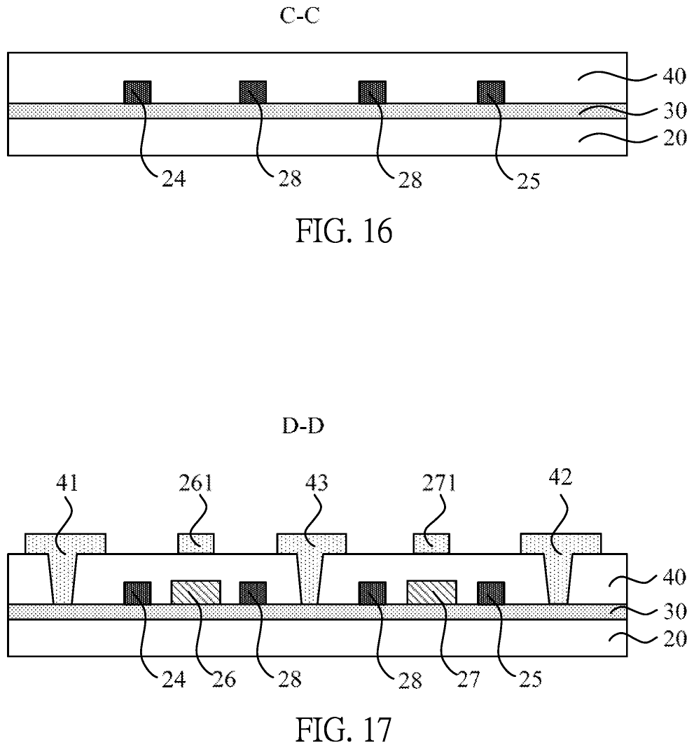

FIG. 16 is a schematic cross-sectional view taken along line C-C of the tunable reflector shown in FIG. 2;

FIG. 17 is a schematic cross-sectional view taken along line D-D of the tunable reflector shown in FIG. 2;

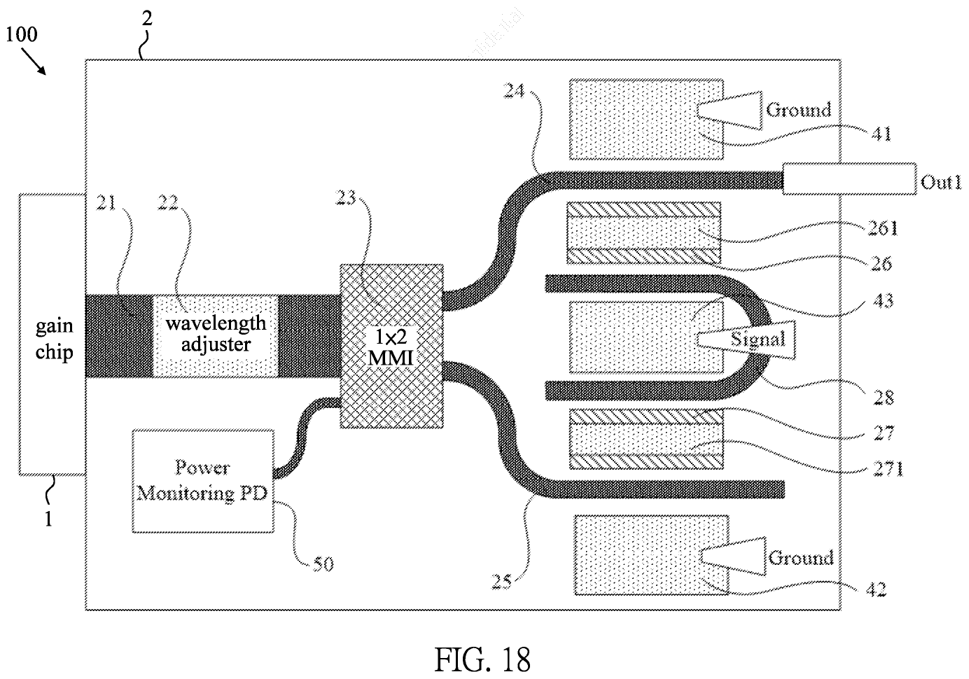

FIG. 18 is a schematic stereoscopic view of a structure of a tunable reflector in still another external cavity laser according to one embodiment;

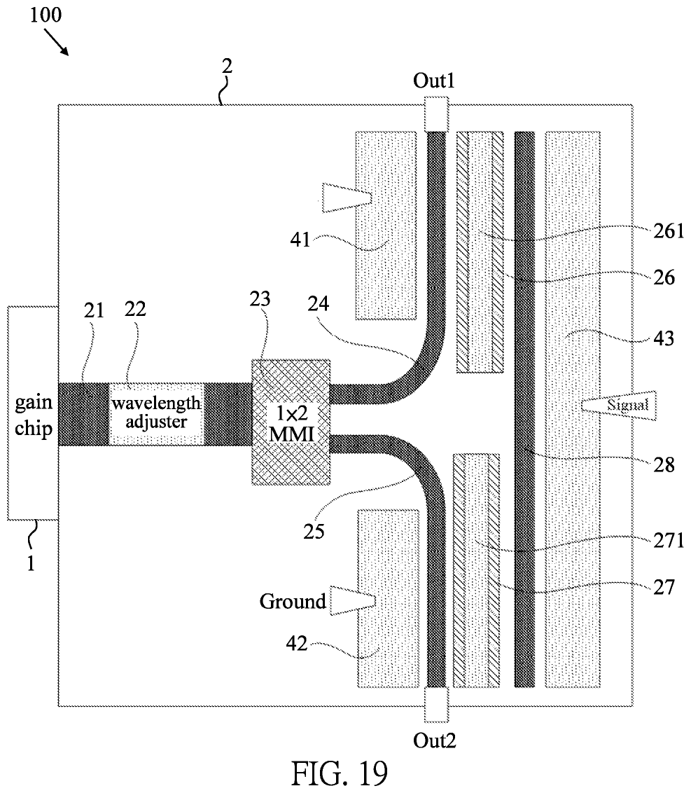

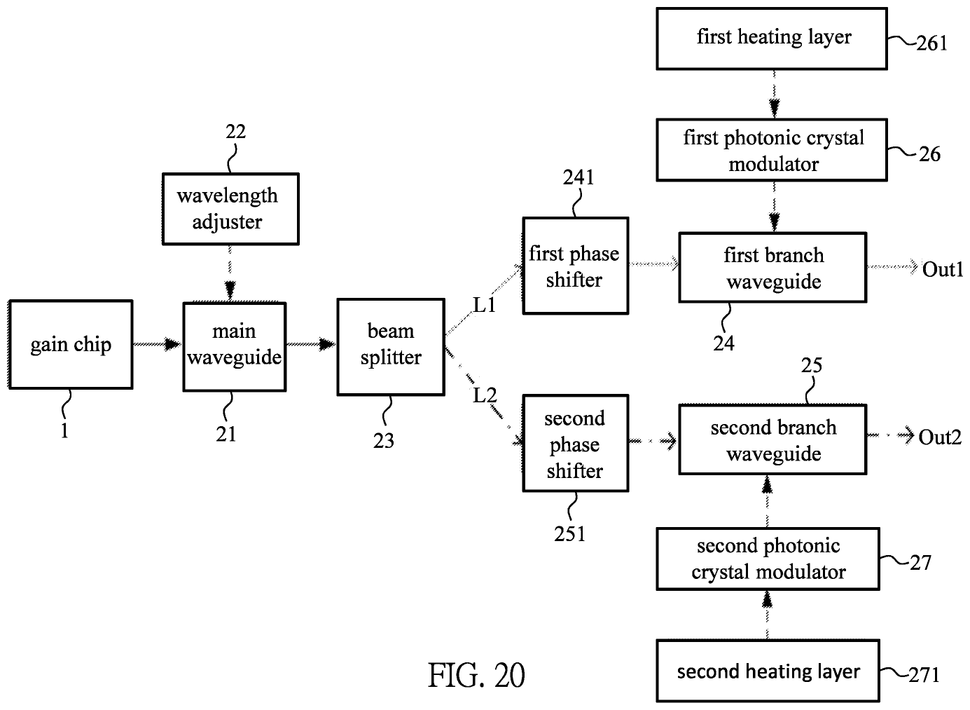

FIG. 19 is a schematic stereoscopic view of a structure of a tunable reflector in yet another external cavity laser according to one embodiment;

FIG. 20 is a schematic view of an optical signal tuning of an external cavity laser according to one embodiment;

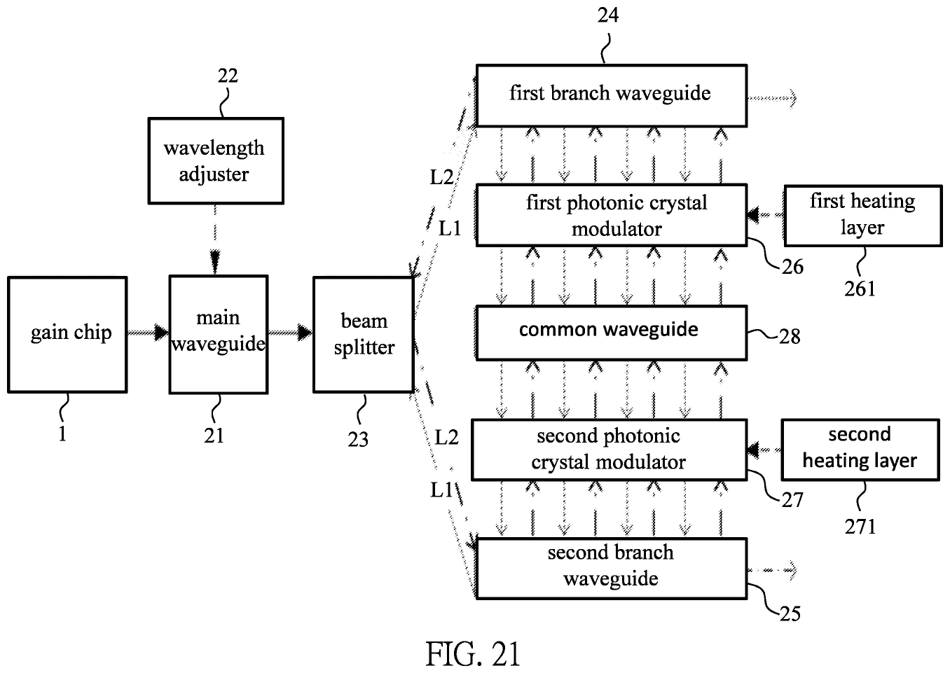

FIG. 21 is a schematic view of an optical signal tuning of another external cavity laser according to one embodiment; and

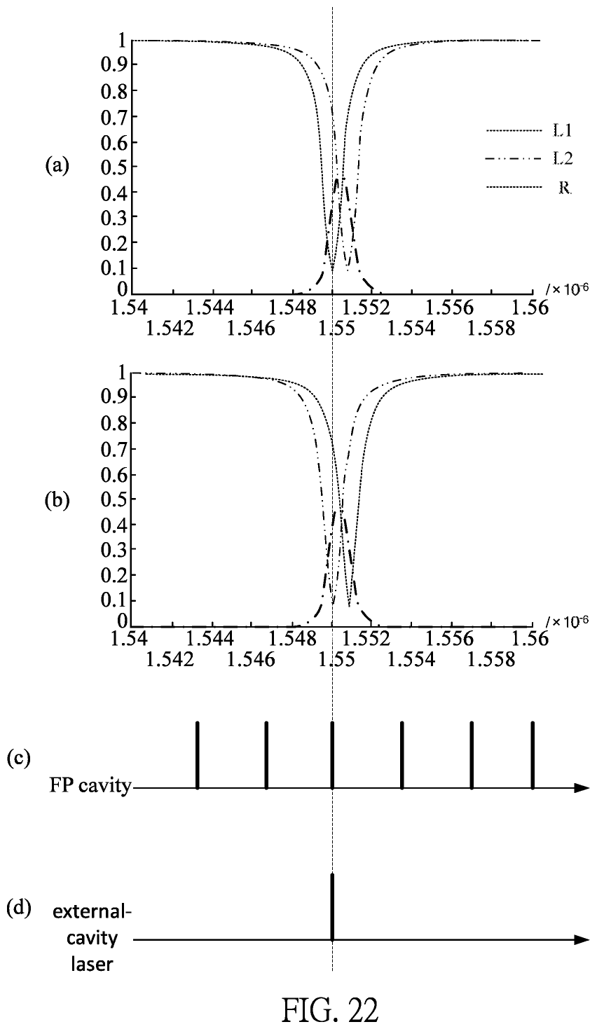

FIG. 22 is an optical transmission spectrum view of an external cavity laser according to one embodiment.

### EXPLANATION OF REFERENCE SYMBOLS

100—external cavity laser, 1—gain chip, 2—tunable reflector,
21—main waveguide, 22—wavelength adjuster, 23—beam splitter, 24—first branch waveguide, 241—first phase shifter,
25—second branch waveguide, 251—second phase shifter, 26—first photonic crystal modulator,
261—first heating layer, 27—second photonic crystal modulator, 271—second heating layer,
28—common waveguide, 20—lower cladding layer, 30—semiconductor layer, 40—upper cladding layer, 50—power monitor,
60—photonic crystal modulation structure, 41—first electrode, 42—second electrode, 43—common electrode,
R1—resonant cavity of the first photonic crystal modulator, R2—resonant cavity of the second photonic crystal modulator;
L1—first optical signal, L2—second optical signal, R-reflected optical signal.

### EMBODIMENTS OF THE DISCLOSURE

### Detailed Description of the Exemplary Embodiments

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

In order to facilitate the understanding of the present disclosure, the present disclosure will be more fully described below with reference to the relevant drawings. Embodiments of the present disclosure are shown in the drawings. However, the present disclosure may be implemented in many different forms and is not limited to the embodiments described herein. On the contrary, these embodiments are provided to make the present disclosure of this application more thorough and comprehensive.

Unless otherwise defined, all technical and scientific terms used herein have the same meanings as commonly understood by those skilled in the technical field of the present disclosure. The terms used in the specification of the present disclosure are only for the purpose of describing specific embodiments, and are not intended to limit the present disclosure.

It should be understood that when an element or layer is referred to as being “on”, “adjacent to”, “connected to” or “coupled to” another element or layer, it may be directly on, adjacent to, connected to or coupled to another element or layer, or an intervening element or layer may exist. On the contrary, when an element is referred to as being “directly on”, “directly adjacent to”, “directly connected to” or “directly coupled to” another element or layer, there is no intervening element or layer.

It should be understood that although the terms first, second, etc. may be used to describe various elements, components, areas, layers, doping types and/or portions, these elements, components, areas, layers, doping types and/or portions should not be limited by these terms. These terms are only used to distinguish one element, component, area, layer, doping type or portion from another element, component, area, layer, doping type or portion. Therefore, without departing from the teachings of the present disclosure, a first element, component, area, layer, doping type or portion discussed below may be represented as a second element, component, area, layer or portion.

Spatial relation terms such as “under”, “below”, “lower”, “beneath”, “on” and “upper” etc. may be used here for describing the relationship between one element or feature and another element or feature shown in the drawings. It should be understood that in addition to the orientations shown in the drawings, the spatial relationship terms are intended to include different orientations of devices in use and operation. For instance, if the device in the drawings is turned upside down, then an element or feature described as being “under” or “beneath” or “below” another element or feature will be oriented “on” another element or feature. Therefore, the exemplary terms “below” and “under” may include two orientations, on and under. In addition, the device may also include another orientation (for instance, rotated by 90 degrees or other orientations), and the spatial description used here is interpreted accordingly.

As used herein, the singular forms “an”, “a” and “said/the” may also include plural forms, unless the context clearly indicates otherwise. It should also be understood that the terms “include/comprise” or “have” etc. specify the presence of stated features, integers, steps, operations, components, portions or their combinations, but do not exclude the possibility of the presence or addition of one or more other features, integers, steps, operations, components, portions or their combinations. Moreover, in this specification, the term “and/or” includes any and all combinations of related listed items.

The embodiments of the present disclosure are described here with reference to cross-sectional views that are schematic diagrams of ideal embodiments (and intermediate structures) of the present disclosure, so that changes in the shown shapes due to, for instance, manufacturing techniques and/or tolerances can be expected. Therefore, the embodiments of the present disclosure should not be limited to the specific shapes of the areas shown here, but include shape deviations due to, for example, the manufacturing techniques. The areas shown in the drawings are schematic in nature, and their shapes do not represent the practical shapes of the areas of the device, and do not limit the scope of the present disclosure.

At present, external cavity lasers have been widely used in many scientific and technological industries such as military, industry, agriculture, aviation, communications, medicine, etc. due to their advantages such as high efficiency, long life, stable frequency, and wide wavelength tuning range.

Referring to FIG. 1 and FIG. 2, some embodiments of the present disclosure provide an external cavity laser 100. The external cavity laser 100 is, for instance, a silicon-based III/V hybrid integrated laser.

It should be noted that FIG. 1 and FIG. 2 only show the structure of an external cavity feedback element in the external cavity laser 100. The structures of other components of the external cavity laser 100 can be found in related technologies, and will not be described in detail in this embodiment of the present disclosure.

As shown in FIG. 1 and FIG. 2, the external cavity laser 100 includes a gain chip 1 and a tunable reflector 2 coupled with the gain chip 1. The tunable reflector 2 includes a main waveguide 21, a beam splitter 23, a first branch waveguide 24, a second branch waveguide 25, a first photonic crystal modulator 26, and a second photonic crystal modulator 27.

The main waveguide 21 is coupled to the gain chip 1 and is configured to receive an optical signal transmitted by the gain chip 1.

The gain chip 1 has a gain medium and a high-reflection surface. The gain chip 1 is, for instance, a reflective Semiconductor Optical Amplifier (RSOA). The main waveguide 21 is, for instance, a silicon-based planar waveguide. The gain chip 1 can be coupled to an input port of the main waveguide 21 through end-face coupling (including surface vertical coupling) or grating coupling.

The beam splitter 23 is coupled to the main waveguide 21 and is configured to equally split the optical signal transmitted by the main waveguide 21 into a first optical signal and a second optical signal.

The beam splitter 23 is used to equally split the optical signal to achieve equal division of optical power. The beam splitter 23 can be a Y branch waveguide, a 1×2 Multi-Mode Interference (MMI) coupler, a 2×2 multimode interference coupler, or a directional coupler with a beam splitting ratio of 50:50, and so on. The embodiment of the present disclosure does not limit thereto, and it can be selected according to practical requirements.

The first branch waveguide 24 is coupled to the beam splitter 23 and is configured to receive the first optical signal. The first photonic crystal modulator 26 is arranged beside the first branch waveguide 24 and is configured to tune the first optical signal transmitted by the first branch waveguide 24.

The second branch waveguide 25 is coupled to the beam splitter 23 and is configured to receive the second optical signal. The second photonic crystal modulator 27 is arranged beside the second branch waveguide 25 and is configured to tune the second optical signal transmitted by the second branch waveguide 25.

The first branch waveguide 24 and the second branch waveguide 25 are, for instance, silicon-based planar waveguides.

The first photonic crystal modulator 26 and the second photonic crystal modulator 27 are formed of photonic crystal materials, which have the advantages of smaller size, larger output power, and smaller equivalent reflection change, and will not be affected by the Free Spectral Range (FSR). Moreover, the first photonic crystal modulator 26 and the second photonic crystal modulator 27 have only one resonance peak in the operating band, so they are not easily affected by the inter-mode competition effect, thereby achieving a wider operating frequency range and facilitating modulation control.

In the embodiment of the present disclosure, the high-reflection surface of the gain chip 1 and the tunable reflector 2 can jointly form the FP cavity of the external cavity laser 100. The output port of the external cavity laser 100 can be one or more. For instance, the output port of the external cavity laser 100 is the output port Out 1 of the first branch waveguide 24 and/or the output port Out2 of the second branch waveguide 24, but the present disclosure is not limited thereto.

After the gain chip 1 transmits the optical signal to the main waveguide 21 of the tunable reflector 2, the beam splitter 23 can be used to split the optical signal transmitted by the main waveguide into the first optical signal and the second optical signal, and then the first photonic crystal modulator 26 is used to tune the first optical signal, and the second photonic crystal modulator 27 is used to tune the second optical signal. In this way, under the tuning effect of the first photonic crystal modulator 26 and the second photonic crystal modulator 27, as well as the action of beam reflection and beam interference in the FP cavity, the optical signal can be output directly and quickly from an output port of the external cavity laser 100, and thereby achieving high-speed direct modulation of external cavity laser.

In one possible implementation, as shown in FIG. 1, the tunable reflector 2 further includes a first phase shifter 241 and a second phase shifter 251. In addition, the first phase shifter 241 is coupled to the first branch waveguide 24 and is configured to adjust a phase of the first optical signal received by the first branch waveguide 24. The second phase shifter 251 is coupled to the second branch waveguide 25 and is configured to adjust a phase of the second optical signal received by the second branch waveguide 25.

The structures of the first phase shifter 241 and the second phase shifter 251 can be selected and set according to practical requirements, as long as the phase of the corresponding optical signal can be adjusted. In this way, the phases of the first optical signal and the second optical signal are independently adjusted to keep the phases consistent with each other, so as to avoid differences between the first optical signal and the second optical signal due to factors such as process errors or design errors, which may lead to unstable light fields in the FP cavity. This helps ensure that the laser's light output is efficient and stable.

In another one possible implementation, as shown in FIG. 2, the first photonic crystal modulator 26 is arranged on one side of the first branch waveguide 24 close to the second branch waveguide 25, and the second photonic crystal modulator 27 is arranged on one side of the second branch waveguide 25 close to the first branch waveguide 24. The tunable reflector 2 further includes a common waveguide 28, which is arranged between the first photonic crystal modulator 26 and the second photonic crystal modulator 27. The common waveguide 28 is configured to receive the first optical signal tuned by the first photonic crystal modulator 26, and transmit the tuned first optical signal to a resonant cavity of the second photonic crystal modulator 27, so as to be coupled to the second branch waveguide 25 after the secondary tuning by the second photonic crystal modulator 27; and, to receive the second optical signal tuned by the second photonic crystal modulator 27, and transmit the tuned second optical signal to a resonant cavity of the first photonic crystal modulator 26, so as to be coupled to the first branch waveguide 24 after the secondary tuning by the first photonic crystal modulator 26.

In the embodiment of the present disclosure, the structure of the tunable reflector 2 is as shown in FIG. 2.

Based on this, a tuning path view of the first optical signal is shown in FIG. 3. Correspondingly, in this situation, the resonant cavity R1 of the first photonic crystal modulator 26 is as shown in FIG. 4. The resonant cavity R1 at least includes a spatial area with optical signal uploading and downloading functions, which is composed of the first photonic crystal modulator 26 plus the first branch waveguide 24 (Input) and the common waveguide 28 (Drop Output). The resonant cavity R2 of the second photonic crystal modulator 27 is as shown in FIG. 5. The resonant cavity R2 at least includes a spatial area with optical signal uploading and downloading functions, which is composed of the second photonic crystal modulator 27 plus the common waveguide 28 (Input) and the second branch waveguide 25 (Drop Output).

Similarly, a tuning path view of the second optical signal is shown in FIG. 6. Correspondingly, in this situation, the resonant cavity R2 of the second photonic crystal modulator 27 is as shown in FIG. 7. The resonant cavity R2 at least includes a spatial area with optical signal uploading and downloading functions, which is composed of the second photonic crystal modulator 27 plus the second branch waveguide 25 (Input) and the common waveguide 28 (Drop Output). The resonant cavity R1 of the first photonic crystal modulator 26 is as shown in FIG. 8. The resonant cavity R1 at least includes a spatial area with optical signal uploading and downloading functions, which is composed of the first photonic crystal modulator 26 plus the common waveguide 28 (Input) and the first branch waveguide 24 (Drop Output).

In the embodiment of the present disclosure, the common waveguide 28 is arranged between the first photonic crystal modulator 26 and the second photonic crystal modulator 27. The secondary tunings of the first optical signal and the second optical signal can be achieved through the common waveguide 28, that is, push-pull tunings of the first optical signal and the second optical signal in the FP cavity can be achieved, so as to realize the tuning of the optical signal to a vast extent, and allow the tuning of the first optical signal and the second optical signal to have the same optical path (shift). For instance, after the optical signal is equally split into the first optical signal and the second optical signal, the first photonic crystal modulator 26 and the second photonic crystal modulator 27 can perform anti-phase modulation of the two optical signals. That is, under the action of the same input electrical signal, resonance peaks of the first photonic crystal modulator 26 and the second photonic crystal modulator 27 are moved in opposite directions. Therefore, when the first optical signal and the second optical signal are secondary tuned by the first photonic crystal modulator 26 and the second photonic crystal modulator 27, respectively, the change in the resonance peaks between the first photonic crystal modulator 26 and the second photonic crystal modulator 27 can offset the change in the beam reflection in the FP cavity during the modulation process of the first optical signal and the second optical signal to ensure that the FP cavity has stable light reflectivity and stable light field, and thereby ensuring efficient and stable light emission of the external cavity laser.

Additionally, referring to FIG. 4 and FIG. 5, in some embodiments, the first photonic crystal modulator 26 and the second photonic crystal modulator 27 can each be composed of one photonic crystal modulation structure 60, or can be composed of a plurality of photonic crystal modulation structures 60 cascaded. Optionally, the photonic crystal modulation structure 60 is an SOI photonic crystal structure or a SiN photonic crystal structure.

Optionally, the first photonic crystal modulator 26 and the second photonic crystal modulator 27 are respectively composed of multiple photonic crystal modulation structures 60 cascaded along a transmission direction of the corresponding waveguide. In this way, the optical signal located at the resonance peak after being tuned by each photonic crystal modulation structure 60 can enter the adjacent or opposite photonic crystal modulation structure 60 to realize the tuning of the optical signal to a vast extent, and it is beneficial to improve the tuning efficiency and tuning quality of the optical signal by the first photonic crystal modulator 26 and the second photonic crystal modulator 27.

The photonic crystal modulation structure 60 can be arranged in various ways. Among them, according to the dimensions of the photonic crystal, the photonic crystal modulation structure 60 is, for instance, a one-dimensional photonic crystal nanobeam cavity structure as shown in FIG. 9; or a two-dimensional photonic crystal flat plate structure as shown in FIG. 10. According to the shape of the photonic crystal, the photonic crystal modulation structure 60 is, for instance, a cylindrical array structure as shown in FIG. 11, a fishbone structure as shown in FIG. 12, or a hole array structure as shown in FIG. 13. The embodiment of the present disclosure is not limited thereto.

In addition, the resonance peaks of the first photonic crystal modulator 26 and the second photonic crystal modulator 27 are related to their structures, and the design can be selected according to practical requirements. The operating wavelengths of the first photonic crystal modulator 26 and the second photonic crystal modulator 27 can be selected and set according to the requirements of modulation bandwidth and extinction ratio.

Referring to FIG. 1 and FIG. 2, in some embodiments, the tunable reflector 2 further includes a wavelength adjuster 22. In addition, the wavelength adjuster 22 is coupled to the main waveguide 21 and is configured to adjust the wavelength of the optical signal received by the main waveguide 21. In this way, by using the wavelength adjuster 22 to adjust the wavelength of the optical signal received by the main waveguide 21, the wavelength of the optical signal transmitted by the gain chip 1 to the main waveguide 21 can be matched with operating wavelengths of the first photonic crystal modulator 26 and the second photonic crystal modulator 27, so as to ensure that the operating output (i.e. output power, wavelength of output optical signal) of the gain chip 1 would not affected by changes in the modulation states of the first photonic crystal modulator 26 and the second photonic crystal modulator 27.

Optionally, the wavelength adjuster 22 is a phase shifter. The wavelength adjuster 22 can adjust the equivalent length of the FP cavity by adjusting the phase of the optical signal received by the main waveguide 21, so as to change the wavelength of the optical signal received by the main waveguide 21.

In order to more clearly illustrate the structure of the tunable reflector 2 in the embodiment of the present disclosure, some of the following embodiments take the structure shown in FIG. 2 as an example to illustrate its layer structure.

Referring to FIG. 2, FIG. 14, FIG. 15, FIG. 16, and FIG. 17, the tunable reflector 2 further includes a lower cladding layer 20 and an upper cladding layer 40 arranged opposite to each other. The main waveguide 21, the beam splitter 23, the first branch waveguide 24, the first photonic crystal modulator 26, the second branch waveguide 25, the second photonic crystal modulator 27, and the common waveguide 28 are respectively arranged between the lower cladding layer 20 and the upper cladding layer 40.

The lower cladding layer 20 serves as the substrate or insulating carrier of the tunable reflector 2, and can be a silicon substrate or a silicon-based substrate. The upper cladding layer 40 is formed of a light-transmitting insulating material, such as light-transmitting resin, silicon dioxide, and so on.

The upper surface of the lower cladding layer 20 is usually provided with a semiconductor film. In this way, by patterning different areas of the semiconductor film and performing different types of doping, different parts of the semiconductor film can be used to form the semiconductor layer 30, the main waveguide 21, the first branch waveguide 24, the first photonic crystal modulator 26, the second branch waveguide 25, the second photonic crystal modulator 27, the common waveguide 28, and so on.

For instance, the first photonic crystal modulator 26 and the second photonic crystal modulator 27 are each formed by a PN structure doped with a semiconductor film. In addition, the photon lifetimes in the first photonic crystal modulator 26 and the second photonic crystal modulator 27 are related to the tuning quality of their resonant cavities, and can directly affect the modulation bandwidth of the external cavity laser 100. The embodiment of the present disclosure does not limit thereto, and it can be selected according to practical requirements.

On the basis of the above embodiments, referring to FIG. 2 and FIG. 17, the tunable reflector 2 further includes a first electrode 41, a second electrode 42, and a common electrode 43 disposed on an upper surface of the upper cladding layer 40. The first electrode 41, the second electrode 42, and the common electrode 43 are respectively connected to the semiconductor layer 30 via through holes in the upper cladding layer 40.

The first photonic crystal modulator 26 is arranged between the first electrode 41 and the common electrode 43 and is configured to tune the optical signal under the action of the electrical signal provided by the first electrode 41 and the common electrode 43. In this way, the first electrode 41 and the common electrode 43 respectively provide different voltage signals, and the bias voltage between them can be used to adjust the resonance peak of the first photonic crystal modulator 26.

The second photonic crystal modulator 27 is arranged between the second electrode 42 and the common electrode 43 and is configured to tune the optical signal under the action of the electrical signal provided by the second electrode 42 and the common electrode 43. In this way, the second electrode 42 and the common electrode 43 respectively provide different voltage signals, and the bias voltage between them can be used to adjust the resonance peak of the second photonic crystal modulator 27.

Optionally, the first electrode 41 and the second electrode 42 are grounded. The common electrode 43 is connected to an external voltage terminal to receive a modulated voltage signal. On the contrary, it is also allowed that the common electrode 43 is grounded, and the first electrode 41 and the second electrode 42 are respectively connected to external voltage terminals to receive the modulated voltage signal.

Optionally, the first electrode 41, the second electrode 42 and the common electrode 43 are made of metal conductive materials, such as copper, aluminum, tungsten, and so on.

In some embodiments, referring FIG. 2, an orthogonal projection of the common waveguide 28 on the upper cladding layer 40 is a “U” shape. In this way, on the basis of ensuring that the common waveguide 28 can meet the requirements of optical signal transmission, the spatial position of each component in the tunable reflector 2 can be set more reasonably, which is beneficial to reducing the plane area of the tunable reflector 2, so as to reduce the integral size of the external cavity laser 100, thereby increasing the optical modulation speed of the external cavity laser 100.

In addition, referring to FIG. 2 and FIG. 18, the U-shaped opening of the common waveguide 28 can be directed toward the beam splitter 23 or away from the beam splitter 23. In the embodiment shown in FIG. 18, the transmission of optical signals in the common waveguide 28 can be carried out in the opposite direction to the transmission direction of the common waveguide 28 in the embodiment of FIG. 2.

Optionally, the common electrode 43 is located in a concave area of the orthographic projection of the common waveguide 28 on the upper cladding layer 40.

Referring to FIG. 2 and FIG. 17, in some embodiments, the tunable reflector 2 further includes a first heating layer 261 and a second heating layer 271. The first heating layer 261 is disposed on the upper surface of the upper cladding layer 40 and is located within an orthographic projection range of the first photonic crystal modulator 26 on the upper cladding layer 40. The second heating layer 271 is disposed on the upper surface of the upper cladding layer and is located within an orthographic projection range of the second photonic crystal modulator 27 on the upper cladding layer 40.

The first heating layer 261 and the second heating layer 271 can be metal heating layers or silicon heating layers.

Optionally, the first heating layer 261 and the second heating layer 271 are metal heating layers. In this way, the same material as the first electrode 41, the second electrode 42 and the common electrode 43 can be used and formed in one patterning process.

In addition, the first heating layer 261 and the second heating layer 271 can be connected to an external controller to heat under the control of the controller. In this way, after heating by the first heating layer 261, the effective refractive index of the first photonic crystal modulator 26 can be changed, thereby adjusting the resonance peak of the first photonic crystal modulator 26. In the same way, after heating by the second heating layer 271, an effective refractive index of the second photonic crystal modulator 27 can be changed, thereby adjusting the resonance peak of the second photonic crystal modulator 27.

Based on this, through the first heating layer 261 and the second heating layer 271, the resonance peak of the first photonic crystal modulator 26 and the resonance peak of the second photonic crystal modulator 27 can be independently adjusted to ensure that the resonance peaks of the first photonic crystal modulator 26 and the second photonic crystal modulator 27 are consistent with each other, thereby compensating for the resonance peak deviation issue caused by factors such as processing errors, improving the modulation efficiency of the tunable reflector 2, and ensuring its light reflectivity, so as to further ensure efficient and stable light emission from the external cavity laser.

It should be supplemented that, referring to FIG. 18, in some embodiments, the beam splitter 23 is 2×2 MMI. Correspondingly, the tunable reflector 2 further includes a power monitor 50 (Power Monitoring PD) coupled to the beam splitter 23. In this way, the operating status of the beam splitter 23 can be monitored in real time by using the power monitor 50 to ensure that the beam splitter 23 can equally split the optical signal transmitted by the main waveguide 21.

Referring to FIG. 19, in some embodiments, the first branch waveguide 24, the second branch waveguide 25 and the common waveguide 28 can also be arranged in other ways.

For instance, the first branch waveguide 24 extends along a first direction, and the second branch waveguide 25 extends along a second direction; the first direction and the second direction respectively intersect with a transmission direction of the main waveguide 21, and are symmetrical with the transmission direction of the main waveguide 21 as the center. Optionally, the first direction and the second direction are respectively perpendicular to the transmission direction of the main waveguide 21. The first photonic crystal modulator 26 is arranged beside the first branch waveguide 24 along the first direction, and the second photonic crystal modulator 27 is arranged beside the second branch waveguide 25 along the second direction. The common waveguide 28 is disposed on a side of the first photonic crystal modulator 26 away from the first branch waveguide 24, and on a side of the second photonic crystal modulator 27 away from the second branch waveguide 25. The common waveguide 28 is, for instance, a straight waveguide.

In the embodiment of the present disclosure, the functions of the common waveguide 28 and the technical effects it can achieve are the same as those in the aforementioned embodiments, and will not be reiterated herein.

Based on this, for instance, the first electrode 41 can be arranged on a side of the first branch waveguide 24 away from the first photonic crystal modulator 26 along the first direction. The second electrode 42 can be arranged on a side of the second branch waveguide 25 away from the second photonic crystal modulator 27 along the second direction. The common electrode 43 can be disposed on a side of the common waveguide 28 away from the first photonic crystal modulator 26 and the second photonic crystal modulator 27. In this way, the first photonic crystal modulator 26 is arranged between the first electrode 41 and the common electrode 43 and can tune the optical signal under the action of the electrical signal provided by the first electrode 41 and the common electrode 43. The second photonic crystal modulator 27 is arranged between the second electrode 42 and the common electrode 43 and can tune the optical signal under the action of the electrical signal provided by the second electrode 42 and the common electrode 43.

In addition, the relevant features of the first electrode 41, the second electrode 42 and the common electrode 43 can be referred to some of aforementioned embodiments, and will not be reiterated herein.

The structure of the external cavity laser is as described in some of the aforementioned embodiments. Some embodiments of the present disclosure also provide a tuning method for the external cavity laser, as described below.

Referring to FIG. 1, FIG. 2, FIG. 19, FIG. 20, and FIG. 21, the tuning method includes the following steps.

S100, the main waveguide 21 receives an optical signal transmitted by a gain chip 1 and transmits the optical signal to a beam splitter 23.

S200, the beam splitter 23 splits the optical signal into a first optical signal L1 and a second optical signal L2, transmits the first optical signal L1 to a first branch waveguide 24, and transmits the second optical signal L2 to a second branch waveguide 25.

S300, the first photonic crystal modulator 26 tunes the first optical signal L1 transmitted by the first branch waveguide 24.

S400, the second photonic crystal modulator 27 tunes the second optical signal L2 transmitted by the second branch waveguide 25.

In the embodiment of the present disclosure, the high-reflection surface of the gain chip 1 and the tunable reflector 2 can jointly form the FP cavity of the external cavity laser 100. After the main waveguide 21 receives the optical signal transmitted by the gain chip 1, the beam splitter 23 can be used to split the optical signal transmitted by the main waveguide 21 into the first optical signal L1 and the second optical signal L2, and then the first photonic crystal modulator 26 is used to tune the first optical signal L1, and the second photonic crystal modulator 27 is used to tune the second optical signal L2. In this way, under the tuning effect of the first photonic crystal modulator 26 and the second photonic crystal modulator 27, as well as the action of beam reflection and beam interference in the FP cavity, the optical signal can be output directly and quickly from an output port of the external cavity laser 100, and thereby achieving high-speed direct modulation of external cavity laser.

Depending on the structure of the external cavity laser 100, the corresponding specific tuning methods are also different.

In some embodiments, the structure of the external cavity laser 100 is shown in FIG. 1. Referring to FIG. 20, the tuning method of the external cavity laser 100 further includes the following steps.

S210, before the first photonic crystal modulator 26 tunes the first optical signal L1 transmitted through the first branch waveguide 24, a phase of the first optical signal L1 is adjusted through a first phase shifter 241 so that the phase of the first optical signal L1 is consistent with a phase of the second optical signal L2.

S220, before the second photonic crystal modulator 27 tunes the second optical signal L2 transmitted through the second branch waveguide 25, the phase of the second optical signal L2 is adjusted through a second phase shifter 251 so that the phase of the second optical signal L2 is consistent with the phase of the first optical signal L1.

In the embodiment of the present disclosure, the phases of the first optical signal L1 and the second optical signal L2 are independently adjusted to keep the phases consistent with each other, so as to avoid differences between the first optical signal L1 and the second optical signal L2 due to factors such as process errors or design errors, which may lead to unstable light fields in the FP cavity. This helps ensure that the laser's light output is efficient and stable.

In other embodiments, the structure of the external cavity laser 100 is as shown in FIG. 2 and FIG. 19. Referring to FIG. 21, the tuning method of the external cavity laser 100 further includes the following steps.

S350, the first photonic crystal modulator 26 couples the tuned first optical signal L1 to the common waveguide 28, and the common waveguide 28 transmits the tuned first optical signal L1 into a resonant cavity of the second photonic crystal modulator 27, and the second photonic crystal modulator 27 performs secondary tuning on the tuned first optical signal L1 and couples the secondarily tuned first optical signal L1 to the second branch waveguide 25.

S450, the second photonic crystal modulator 27 couples the tuned second optical signal L2 to the common waveguide 28, and the common waveguide 28 transmits the tuned second optical signal L2 into a resonant cavity of the first photonic crystal modulator 26, and the first photonic crystal modulator 26 performs secondary tuning on the tuned second optical signal L2 and couples the secondarily tuned second optical signal L2 to the first branch waveguide 24.

In the embodiment of the present disclosure, the secondary tunings of the first optical signal L1 and the second optical signal L2 can be achieved through the common waveguide 28, that is, push-pull tunings of the first optical signal L1 and the second optical signal L2 in the FP cavity can be achieved, so as to realize the tuning of the optical signal to a vast extent, and allow the tuning of the first optical signal L1 and the second optical signal L2 to have the same optical path (shift). For instance, after the optical signal is equally split into the first optical signal L1 and the second optical signal L2, the first photonic crystal modulator 26 and the second photonic crystal modulator 27 can perform anti-phase modulation of the two optical signals. That is, under the action of the same input electrical signal, resonance peaks of the first photonic crystal modulator 26 and the second photonic crystal modulator 27 are moved in opposite directions. Therefore, when the first optical signal L1 and the second optical signal L2 are secondary tuned by the first photonic crystal modulator 26 and the second photonic crystal modulator 27, respectively, the change in the resonance peaks between the first photonic crystal modulator 26 and the second photonic crystal modulator 27 can offset the change in the beam reflection in the FP cavity during the modulation process of the first optical signal L1 and the second optical signal L2 to ensure that the FP cavity has stable light reflectivity and stable light field, and thereby ensuring efficient and stable light emission of the external cavity laser.

In some embodiments, referring to FIG. 19 and FIG. 20, the tuning method of the external cavity laser further includes the following steps.

S001, adjusting the resonance peak of the first photonic crystal modulator 26 through the first heating layer 261 to make the resonance peak of the first photonic crystal modulator 26 consistent with the resonance peak of the second photonic crystal modulator 27.

S002, adjusting the resonance peak of the second photonic crystal modulator 27 through the second heating layer 271 to make the resonance peak of the second photonic crystal modulator 27 consistent with the resonance peak of the first photonic crystal modulator 26.

There is no sequence restriction between S001 and S300, and between S002 and S400 here, that is, any previous execution or simultaneous execution is allowed.

In the embodiment of the present disclosure, through the first heating layer 261 and the second heating layer 271, the resonance peak of the first photonic crystal modulator 26 and the resonance peak of the second photonic crystal modulator 27 can be independently adjusted to ensure that the resonance peaks of the first photonic crystal modulator 26 and the second photonic crystal modulator 27 are consistent with each other, thereby compensating for the resonance peak deviation issue caused by factors such as processing errors, improving the modulation efficiency of the tunable reflector 2, and ensuring its light reflectivity, so as to further ensure efficient and stable light emission from the external cavity laser.

In some embodiments, referring to FIG. 19 and FIG. 20, the tuning method of the external cavity laser further includes the following steps.

S110, adjusting the wavelength of the optical signal by the wavelength adjuster 22 before the main waveguide 21 transmitting the optical signal to the beam splitter 23, so as to make the wavelength of the optical signal consistent with an operating wavelength of the first photonic crystal modulator 26 and an operating wavelength of the second photonic crystal modulator 27.

The wavelength adjuster 22 is, for instance, a phase shifter. The wavelength adjuster 22 can adjust the equivalent length of the FP cavity by adjusting the phase of the optical signal received by the main waveguide 21, so as to change the wavelength of the optical signal received by the main waveguide 21.

In this embodiment, by using the wavelength adjuster 22 to adjust the wavelength of the optical signal received by the main waveguide 21, the wavelength of the optical signal transmitted by the gain chip 1 to the main waveguide 21 can be matched with operating wavelengths of the first photonic crystal modulator 26 and the second photonic crystal modulator 27, so as to ensure that the operating output (i.e. output power, wavelength of output optical signal) of the gain chip 1 would not affected by changes in the modulation states of the first photonic crystal modulator 26 and the second photonic crystal modulator 27.

It should be understood that, unless explicitly stated herein, there is no strict order restriction on the execution of some steps in the tuning method of the external cavity laser 100. These steps can be performed selectively according to the signal to be modulated by the external cavity laser 100, or may be performed in another order, that is, the order of execution of these steps is not necessarily sequential.

The external cavity laser 100 and the tuning method thereof provided by the embodiments of the present disclosure are as described above. After simulating the external cavity laser 100, the optical transmission spectrum of each signal in the external cavity laser 100 is shown in FIG. 22. Specifically, FIG. 22(a) shows the transmission spectra of the first optical signal L1 and the second optical signal L2, and the reflection spectrum of the equivalent reflected light R in the FP cavity under a first state, for instance, an on state (0) of the laser. FIG. 22(b) shows the transmission spectra of the first optical signal L1 and the second optical signal L2, and the reflection spectrum of the equivalent reflected light R in the FP cavity under a second state, for instance, an off state (1) of the laser. FIG. 22(c) shows the resonance peak spectrum of the FP cavity in the external cavity laser 100. FIG. 22(d) shows the spectrum of the optical signal output by the external cavity laser 100.

In this way, it can be seen from FIG. 22 that when the external cavity laser 100 responds to different states, the FP cavity can have a stable and unified narrow-band reflection spectrum to ensure the stability of the light field in the FP cavity, thereby ensuring efficient and stable light emission of the external cavity laser.

The resonant cavities of the first photonic crystal modulator 26 and the second photonic crystal modulator 27 can only have one resonant peak. After the wavelength adjuster 22 is used to adjust the wavelength of the optical signal input by the gain chip 1 to make the wavelength matches the operating wavelengths of the first photonic crystal modulator 26 and the second photonic crystal modulator 27, the optical signal with the same wavelength as the resonance peak has a reflectivity in the FP cavity that is much greater than that of optical signals with other wavelengths can be ensured by the modulation of the optical signal by the first photonic crystal modulator 26 and the second photonic crystal modulator 27. Therefore, the optical signal becomes the only output optical signal of the external cavity laser 100, for instance, as shown in FIG. 22(d).

Therefore, the first photonic crystal modulator 26 and the second photonic crystal modulator 27 have a wavelength selection function, and can achieve effective modulation of the optical signal by the first photonic crystal modulator 26 and the second photonic crystal modulator 27 without affecting the output power of the gain chip 1, thereby accurately modulating the wavelength of the output optical signal of the external cavity laser 100.

In summary, during the process of push-pull tuning of the optical signal by using the first photonic crystal modulator 26 and the second photonic crystal modulator 27, the beam reflectivity in the FP cavity of the external cavity laser 100 can remain stable. Therefore, after using a constant current to drive the gain chip 1, the light field in the FP cavity is stable, which can ensure that the output optical signal of the external cavity laser 100 is not affected by the dynamic response of the external cavity laser 100.

Based on this, by adjusting the wavelength of the optical signal transmitted by the main waveguide 21 through the wavelength adjuster 22, so as to make the wavelength is matched and aligned with the operating wavelengths of the first photonic crystal modulator 26 and the second photonic crystal modulator 27, the stable output of the single-wavelength optical signal of the external cavity laser 100 can be achieved. Therefore, the wavelength adjustment range of the external cavity laser 100 can be greatly reduced, and the wavelength control of the external cavity laser 100 can be simplified.

In the description of this specification, the technical features of the above-mentioned embodiments may be arbitrarily combined. In order to make the description concise, not all possible combinations of the technical features of the above-mentioned embodiments are described. However, as long as there is no contradiction between the combinations of these technical features, the combinations shall be considered within the scope of this specification.

The above-mentioned embodiments only describe several implementation modes of this disclosure, and their descriptions are comparatively specific and detailed, but should not be understood as limiting the scope of the patent disclosure. It should be noted that, for those of ordinary skill in the art, without departing from the concept of this disclosure, several modifications and improvements can be made, all of which are within the scope of protection of this disclosure. Therefore, the scope of protection of this patent disclosure should be subject to the appended claims.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An external cavity laser, characterized in that, the external cavity laser comprises a gain chip, and a tunable reflector coupled with the gain chip;
wherein the tunable reflector includes:
a main waveguide coupled to the gain chip and configured to receive an optical signal transmitted by the gain chip;
a beam splitter coupled to the main waveguide and configured to equally split the optical signal transmitted by the main waveguide into a first optical signal and a second optical signal;
a first branch waveguide coupled to the beam splitter and configured to receive the first optical signal;
a first photonic crystal modulator arranged beside the first branch waveguide and configured to tune the first optical signal transmitted by the first branch waveguide;
a second branch waveguide coupled to the beam splitter and configured to receive the second optical signal; and
a second photonic crystal modulator arranged beside the second branch waveguide and configured to tune the second optical signal transmitted by the second branch waveguide.

2. The external cavity laser according to claim 1, characterized in that the tunable reflector further includes a common waveguide;
wherein the first photonic crystal modulator is arranged on one side of the first branch waveguide close to the second branch waveguide, and the second photonic crystal modulator is arranged on one side of the second branch waveguide close to the first branch waveguide;
wherein the common waveguide is arranged between the first photonic crystal modulator and the second photonic crystal modulator, and is configured to receive the first optical signal tuned by the first photonic crystal modulator, and transmit the first optical signal after tuned to a resonant cavity of the second photonic crystal modulator, so as to be coupled to the second branch waveguide after the secondary tuning by the second photonic crystal modulator; and, to receive the second optical signal tuned by the second photonic crystal modulator, and transmit the second optical signal after tuned to a resonant cavity of the first photonic crystal modulator, so as to be coupled to the first branch waveguide after the secondary tuning by the first photonic crystal modulator.

3. The external cavity laser according to claim 2, characterized in that the tunable reflector further includes a lower cladding layer and an upper cladding layer arranged opposite to each other;
wherein the main waveguide, the beam splitter, the first branch waveguide, the first photonic crystal modulator, the second branch waveguide, the second photonic crystal modulator, and the common waveguide are respectively arranged between the lower cladding layer and the upper cladding layer.

4. The external cavity laser according to claim 3, characterized in that an upper surface of the lower cladding layer is provided with a semiconductor layer and the tunable reflector further includes a first electrode, a second electrode, and a common electrode;
wherein the first electrode, the second electrode, and the common electrode are respectively disposed on an upper surface of the upper cladding layer, and are respectively connected to the semiconductor layer via through holes in the upper cladding layer;
wherein the first photonic crystal modulator is arranged between the first electrode and the common electrode and is configured to tune the optical signal under the action of the electrical signal provided by the first electrode and the common electrode;
wherein the second photonic crystal modulator is arranged between the second electrode and the common electrode and is configured to tune the optical signal under the action of the electrical signal provided by the second electrode and the common electrode.

5. The external cavity laser according to claim 3, characterized in that an orthogonal projection of the common waveguide on the upper cladding layer is a “U” shape.

6. The external cavity laser according to claim 5, characterized in that, when the tunable reflector includes the common electrode, the common electrode is located in a concave area of the orthographic projection of the common waveguide on the upper cladding layer.

7. The external cavity laser according to claim 3, characterized in that the tunable reflector further includes:
a first heating layer disposed on the upper surface of the upper cladding layer and located within an orthographic projection range of the first photonic crystal modulator on the upper cladding layer; and
a second heating layer disposed on the upper surface of the upper cladding layer and located within an orthographic projection range of the second photonic crystal modulator on the upper cladding layer.

8. The external cavity laser according to claim 1, characterized in that the tunable reflector further includes a common waveguide;
wherein the first branch waveguide extends along a first direction, and the second branch waveguide extends along a second direction; wherein the first direction and the second direction respectively intersect with a transmission direction of the main waveguide, and are symmetrical with the transmission direction of the main waveguide as the center; wherein the first photonic crystal modulator is arranged beside the first branch waveguide along the first direction, and the second photonic crystal modulator is arranged beside the second branch waveguide along the second direction;
wherein the common waveguide is disposed on a side of the first photonic crystal modulator away from the first branch waveguide, and on a side of the second photonic crystal modulator away from the second branch waveguide; wherein the common waveguide is configured to receive the first optical signal tuned by the first photonic crystal modulator and transmit the tuned first optical signal into the resonant cavity of the second photonic crystal modulator, so as to be coupled to the second branch waveguide after being secondary tuning by the second photonic crystal modulator; and, to receive the second optical signal tuned by the second photonic crystal modulator, and transmit the tuned second optical signal to the resonant cavity of the first photonic crystal modulator, so as to be coupled to the first branch waveguide after being secondary tuning by the first photonic crystal modulator.

9. The external cavity laser according to claim 8, characterized in that the common waveguide includes a straight waveguide.

10. The external cavity laser according to claim 1, characterized in that the tunable reflector further includes:
a first phase shifter coupled to the first branch waveguide and configured to adjust a phase of the first optical signal received by the first branch waveguide; and
a second phase shifter coupled to the second branch waveguide and configured to adjust a phase of the second optical signal received by the second branch waveguide.

11. The external cavity laser according to claim 1, characterized in that the tunable reflector further includes:
a wavelength adjuster coupled to the main waveguide and configured to adjust the wavelength of the optical signal received by the main waveguide.

12. The external cavity laser according to claim 1, characterized in that the first photonic crystal modulator and the second photonic crystal modulator each includes one photonic crystal modulation structure, or a plurality of cascaded photonic crystal modulation structures.

13. The external cavity laser according to claim 12, characterized in that the photonic crystal modulation structure includes a one-dimensional photonic crystal nanobeam cavity structure or a two-dimensional photonic crystal flat plate structure.

14. The external cavity laser according to claim 12, characterized in that the photonic crystal modulation structure includes a cylindrical array structure, a fishbone structure, or a hole array structure.

15. The external cavity laser according to claim 1, characterized in that the beam splitter includes a Y-branch waveguide, a 1><2 multimode interference coupler, a 2><2 multimode interference coupler, or a directional coupler with a beam splitting ratio of 50:50.

16. A tuning method for an external cavity laser, characterized in that, comprising:
a main waveguide receives an optical signal transmitted by a gain chip and transmits the optical signal to a beam splitter;
the beam splitter splits the optical signal into a first optical signal and a second optical signal, transmits the first optical signal to a first branch waveguide, and transmits the second optical signal to a second branch waveguide;
a first photonic crystal modulator tunes the first optical signal transmitted by the first branch waveguide; and
a second photonic crystal modulator tunes the second optical signal transmitted by the second branch waveguide.

17. The tuning method for an external cavity laser according to claim 16, characterized in that a tunable reflector of the external cavity laser further includes a common waveguide;
the tuning method further comprises:
the first photonic crystal modulator couples the tuned first optical signal to the common waveguide, and the common waveguide transmits the tuned first optical signal into a resonant cavity of the second photonic crystal modulator, and the second photonic crystal modulator performs secondary tuning on the tuned first optical signal and couples the secondarily tuned first optical signal to the second branch waveguide; and
the second photonic crystal modulator couples the tuned second optical signal to the common waveguide, and the common waveguide transmits the tuned second optical signal into a resonant cavity of the first photonic crystal modulator, and the first photonic crystal modulator performs secondary tuning on the tuned second optical signal and couples the secondarily tuned second optical signal to the first branch waveguide.

18. The tuning method for an external cavity laser according to claim 16, characterized in that the tunable reflector of the external cavity laser further includes a first heating layer and a second heating layer;
the tuning method further comprises:
adjusting a resonant peak of the first photonic crystal modulator through the first heating layer, so as to make the resonance peak of the first photonic crystal modulator consistent with a resonance peak of the second photonic crystal modulator; and
adjusting the resonant peak of the second photonic crystal modulator through the second heating layer, so as to make the resonance peak of the second photonic crystal modulator consistent with the resonance peak of the first photonic crystal modulator.

19. The tuning method for an external cavity laser according to claim 18, characterized in that the tunable reflector of the external cavity laser further includes a wavelength adjuster;
the tuning method further comprises:
adjusting the wavelength of the optical signal by the wavelength adjuster before the main waveguide transmitting the optical signal to the beam splitter, so as to make the wavelength of the optical signal consistent with an operating wavelength of the first photonic crystal modulator and an operating wavelength of the second photonic crystal modulator.

20. The tuning method for an external cavity laser according to claim 16, characterized in that the tunable reflector of the external cavity laser further includes a first phase shifter and a second phase shifter;
the tuning method further comprises:
adjusting a phase of the first optical signal through the first phase shifter before the first photonic crystal modulator tuning the first optical signal which is transmitted through the first branch waveguide, so as to make the phase of the first optical signal consistent with a phase of the second optical signal; and
adjusting the phase of the second optical signal through the second phase shifter before the second photonic crystal modulator tuning the second optical signal which is transmitted through the second branch waveguide, so as to make the phase of the second optical signal consistent with the phase of the first optical signal.
